(19) United States
(12) Patent Application Publication
(10) Pub. No.: US 2016/0071726 A1
(43) Pub. Date: Mar. 10, 2016

(54) METHOD OF MANUFACTURING SEMICONDUCTOR DEVICE

(71) Applicant: KABUSHIKI KAISHA TOSHIBA, Tokyo (JP)

(72) Inventors: Hiroshi MIZUNO, Oita Oita (JP); Takeshi SUNADA, Oita Oita (JP); Mokuji KAGEYAMA, Oita Oita (JP); Tadashi MATSUNO, Kanazawa Ishikawa (JP)

(21) Appl. No.: 14/624,249

(22) Filed: Feb. 17, 2015

(30) Foreign Application Priority Data
Sep. 4, 2014 (JP) 2014-180609

(51) Int. Cl. H01L 21/02; H01L 21/3105; H01L 21/311; H01L 21/66; H01L 21/027

(52) U.S. Cl. CPC H01L 21/02288; H01L 22/20; H01L 21/0274; H01L 21/31144; H01L 21/31055; H01L 21/02318

(57) ABSTRACT

A method of manufacturing a semiconductor device includes forming a resist pattern on a first film to be processed by using photolithography, forming a dummy pattern on the first film by using a three-dimensional modeling machine, such as a three-dimensional printer. The dummy pattern is provided on a region of the first film that is not occupied by the resist pattern. The first film is then etched using the resist pattern and the dummy pattern as a mask. A second film is then formed on the etched first film and subsequently flattened/planarized using, for example, chemical mechanical polishing.

### CROSS-REFERENCE TO RELATED APPLICATION

This application is based upon and claims the benefit of priority from Japanese Patent Application No. 2014-180609, filed Sep. 4, 2014, the entire contents of which are incorporated herein by reference.

### FIELD

Embodiments described herein relate generally to a method of manufacturing a semiconductor device.

### BACKGROUND

In general, a chemical mechanical polishing (CMP) method is used to flatten (planarize) an upper surface of an insulation film deposited on a semiconductor substrate having an underlying topographic pattern. However, in the CMP method, a nominally planarized insulation film left on the underlying pattern may be uneven in some cases due to variations in the underlying pattern density of gates, wirings, or the like. Therefore, there is a problem that unevenness occurs in the height of the insulation film (a height from a main surface of a semiconductor substrate to a surface of the insulation film) within one semiconductor chip.

In order to solve the unevenness of the insulation film, the following method has been used. In regions in which the underlying pattern density is relatively low, a dummy pattern on the same layer as the underlying pattern (e.g., gates, wirings, etc.) is formed to uniformize (equalize) the underlying pattern density in the semiconductor chip. Accordingly, a flatness of the insulation film ultimately formed thereon is improved.

A typical CMOS device includes a region in which the underlying pattern (of active components/elements) is concentrated (dense) and a region in which the underlying pattern (of active components/elements) is sparse or not present. The dummy pattern is disposed in the region in which an underlying pattern is sparse or not present. Accordingly, a flatness of a surface of the interlayer insulation film is achieved by equalizing the underlying pattern density by the inclusion of dummy pattern elements in the otherwise sparse or empty pattern areas. However, when the underlying device level pattern has been already designed, it will generally be necessary to modify a corresponding pattern on a reticle (or photomask) used in forming the underlying device level pattern in order to introduce a dummy pattern as needed, and thus there is a problem that it takes time and cost to re-design the underlying pattern to incorporate an appropriate dummy pattern.

### DESCRIPTION OF THE DRAWINGS

FIG. 1 is a schematic cross-sectional view illustrating a semiconductor device during a manufacturing process according to an exemplary embodiment.

FIG. 2 is a schematic cross-sectional view illustrating a semiconductor device during a manufacturing process according to an exemplary embodiment.

FIG. 3 is a schematic cross-sectional view illustrating a process for forming a dummy pattern on a semiconductor device during a manufacturing process according to an exemplary embodiment.

FIG. 4 is a schematic cross-sectional view illustrating a first process for forming a dummy pattern on a semiconductor device during a manufacturing process according to an exemplary embodiment.

FIG. 5 is a schematic cross-sectional view illustrating a variant of a first process for forming a dummy pattern on a semiconductor device during a manufacturing process according to an exemplary embodiment.

FIG. 6 is a schematic cross-sectional view illustrating another variant of a first process for forming a dummy pattern on a semiconductor device during a manufacturing process according to an exemplary embodiment.

FIG. 7 is a schematic cross-sectional view illustrating a second process for forming a dummy pattern on a semiconductor device during a manufacturing process according to an exemplary embodiment.

FIG. 8 is a schematic cross-sectional view illustrating a second process for forming a dummy pattern on a semiconductor device during a manufacturing process according to an exemplary embodiment.

FIG. 9 is a schematic cross-sectional view illustrating a second process for forming a dummy pattern on a semiconductor device during a manufacturing process according to an exemplary embodiment.

FIGS. 10 to 13 are schematic cross-sectional views illustrating the semiconductor device in during a manufacturing process according to an exemplary embodiment.

FIGS. 14 to 16 are schematic plan views illustrating processes related to identifying a region in which to place dummy patterns in a semiconductor device manufacturing process according to an exemplary embodiment.

### DETAILED DESCRIPTION

Embodiments provide a method of manufacturing a semiconductor device having an interlayer insulation film with acceptable flatness without altering a photomask/reticle pattern that has already been established or designed.

In general, according to an embodiment, a method of manufacturing a semiconductor device includes: forming a resist pattern on a first film to be processed (first film) using photolithography, then forming a dummy pattern on a region of the first film from which the resist pattern is substantially absent. That is, the resist pattern does not occupy the region of the first film. The dummy pattern is provided using a three-dimensional modeling machine, such as three-dimensional printer, for example. The first film is then etched using the resist pattern and the dummy pattern as a mask. A second film, such as an interlayer insulation film, is formed on the etched first film. The second film thus formed is planarized.

In general, according to another embodiment, a method of manufacturing a semiconductor device, includes: forming a film to be processed on a semiconductor substrate; forming a resist pattern on the film to be processed using photolithography; forming a dummy pattern on a region of the film to be processed on which the resist pattern are rarely present, using a three-dimensional modeling machine; etching the film to be processed with using the resist pattern and the dummy pattern as a mask; removing the resist pattern and the dummy pattern; forming an interlayer insulation film on the semiconductor substrate; and flattening the interlayer insulation film.

Hereinafter, a configuration and a manufacturing method of a semiconductor device of an exemplary embodiment will be described with reference to drawings. In the description, like reference numerals refer to the like elements throughout all figures.

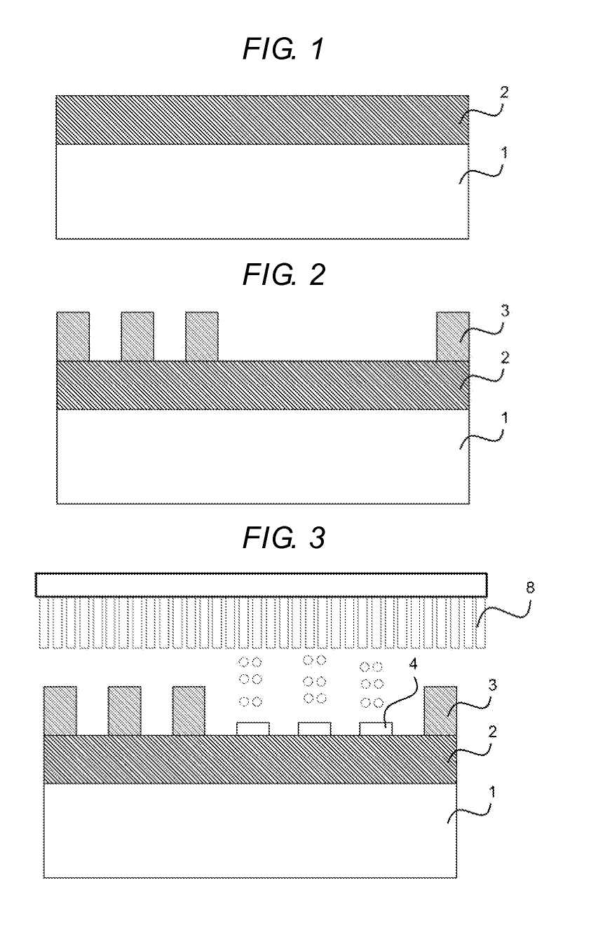

First, as illustrated in FIG. 1, a semiconductor substrate 1 mainly made of silicon (Si) is prepared. Here, a Si single crystal substrate is used as the semiconductor substrate 1; however, single crystal substrates of Ge, SiGe, SiC, GaAs, and the like may be used, and a Silicon-On-Insulator (SOI) substrate may be also used. In addition, the semiconductor substrate 1 may be a polycrystalline or amorphous substrate of the above materials.

Then, as illustrated in FIG. 1, a film to be processed 2 (film 2) is formed on the semiconductor substrate 1. The film 2 is an insulation film such as a silicon oxide film or the like, a semiconductor film of polycrystalline silicon film or the like, or a metal film such as Al or the like.

Then, as illustrated in FIG. 2, a resist pattern 3 is formed on the film 2. The resist pattern 3 is formed by an optical lithography process (e.g., photolithography), for example.

Then, as illustrated in FIG. 3, a dummy pattern 4 is formed on the film 2 in areas in which the resist pattern 3 is sparse or absent. The dummy pattern 4 is formed by applying a resin using a three-dimensional modeling machine (hereinafter, 3D printer). The applied resin may be the same material as, or similar to, the material of the resist pattern 3.

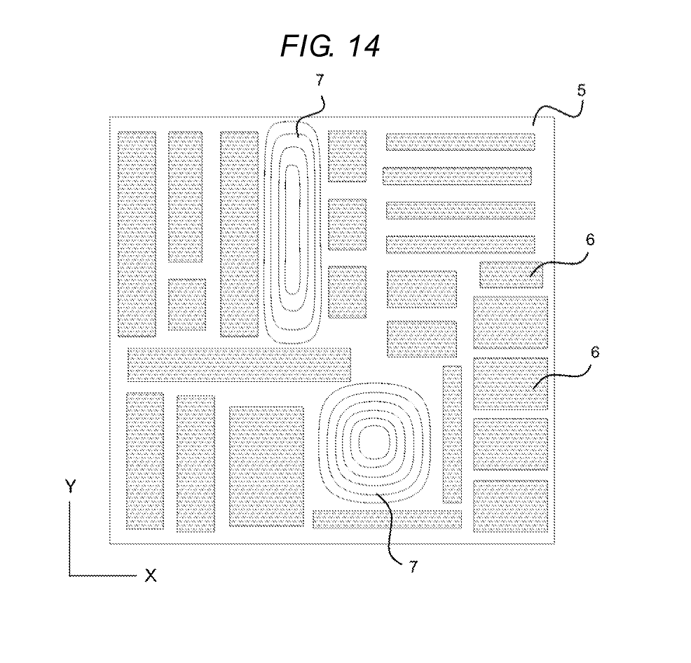

Before forming the dummy pattern 4, a check of a device formed without using the dummy pattern 4 can be performed. The check may involve, for example, one or more test wafers (test substrates) being patterned and processed without using the dummy pattern 4, but otherwise patterned and process in an analogous manner to a substrate having the dummy pattern 4. FIG. 14 is a plan view illustrating one chip on a wafer which has been patterned and then processed by a CMP method to provide a nominally flat insulation film. However, a film thickness of an insulation film which is formed by the CMP method on an underlying pattern 6 (that has pattern density variations), such as on a chip 5 in FIG. 14, is likely to have film thickness unevenness. Since an optical path length varies with film thickness, color unevenness 7 occurs due to differences in interference of reflected light caused by differences in film thickness. In this instance, depicted in FIG. 14, the underlying pattern 6 is formed using a photomask/reticle which has been already designed. That is, the resist pattern used to pattern the underlying film results from a lithographic process using an already existing photomask/reticle. The insulation film was formed on the underlying pattern 6 thus generated, and then the insulation film was subsequently flattened by the CMP method. Then, an optical microscope image on entire surface of the wafer or die was captured to check presence or absence of the color unevenness 7.

Here, a film thickness of an insulation film formed on the semiconductor substrate refers to a thickness from a main surface of the semiconductor substrate to an upper surface of the insulation film (a thickness on the semiconductor substrate), and is not merely a thickness of the insulating film from a surface of the underlying pattern 6 to the upper surface of the insulation film (a thickness of an insulation film on the underlying pattern 6).

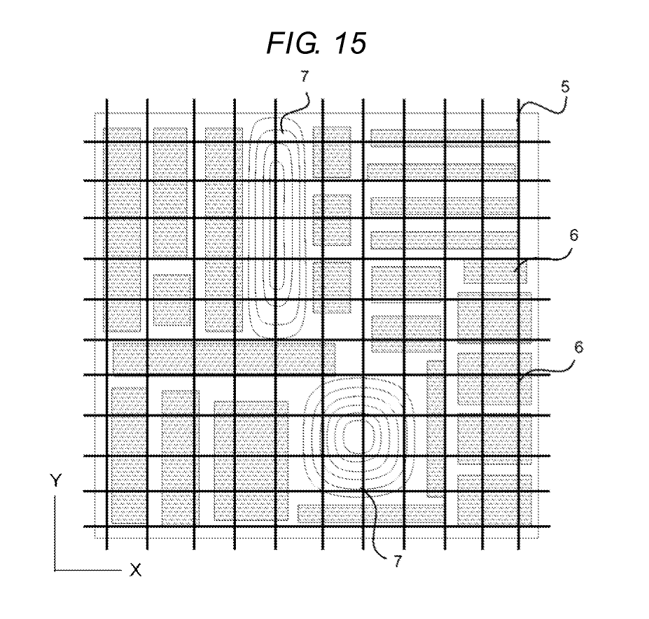

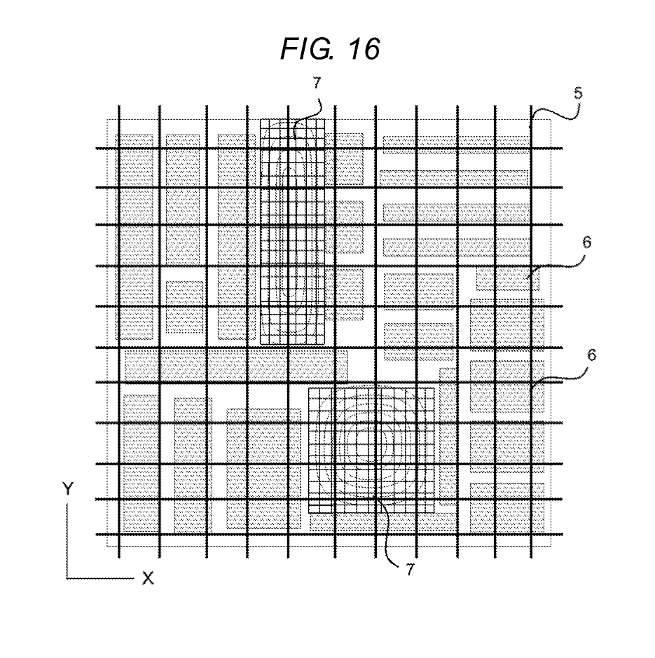

First, a film thickness of the insulation film on the underlying pattern 6 is measured throughout an entire surface of a wafer at one or more points for each chip or die using an optical film thickness measuring instrument to acquire a film thickness dispersion of the insulation film across the wafer plane. Next, as illustrated in FIG. 15, a film thickness measurement is performed by dividing a chip or die area into, for example, ten or more divisions herein in an XY direction to acquire the film thickness dispersion within the chip or die area. Here, as illustrated in FIG. 16, when color unevenness 7 is detected, for example, then a region in which the color unevenness 7 occurs is further divided into ten or more divisions in the XY direction to perform additional film thickness measurements, and film thickness dispersion within the color unevenness 7 region is checked. Even when the color unevenness 7 occurs across a plurality of regions, a place in which the color unevenness 7 occurs is minutely divided in the same manner to perform the film thickness measurement at the plurality of regions, and the film thickness dispersion in the color unevenness 7 can be checked in each. Moreover, since density unevenness of the underlying pattern 6 or film thickness unevenness in an underlying pattern is likely to occur, a measurement location may be added or changed when necessary. Based on these data, that is, based on the measured film thickness unevenness of the insulation film, a design pattern for the dummy pattern 4 is set.

Next, a method of forming the dummy pattern 4 includes two different methods using a 3D printer.

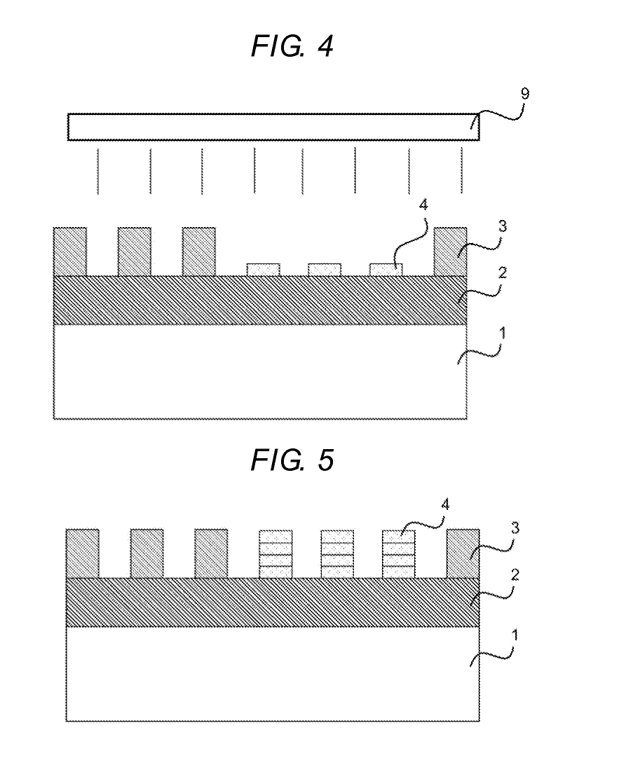

First, an example using a 3D printer including inkjet nozzles 8 and a UV lamp 9 will be described. First, a wafer is placed on a stage of the 3D printer, and a liquid resin is discharged from inkjet nozzles 8 onto an object to be processed (substrate 1). As illustrated in FIG. 3, the liquid resin is dispensed according to a design pattern of the dummy pattern 4 determined using, for example, the across wafer and intra-die film thickness measurement process discussed above. Here, it is desirable to control an inkjet particle size to be on the order of 10 nm so as to create a fine pattern commensurate with the width dimensions of resist pattern 3. The inkjet nozzles 8 and the stage of the 3D printer precisely move with a nanometer order in an X direction, a Y direction, and a Z direction. Then, the resin dispensed according to the design pattern for the dummy pattern 4 is cured by irradiating with ultraviolet light from a UV lamp 9, as illustrated in FIG. 4. In this manner, a first layer of the dummy pattern 4 is printed.

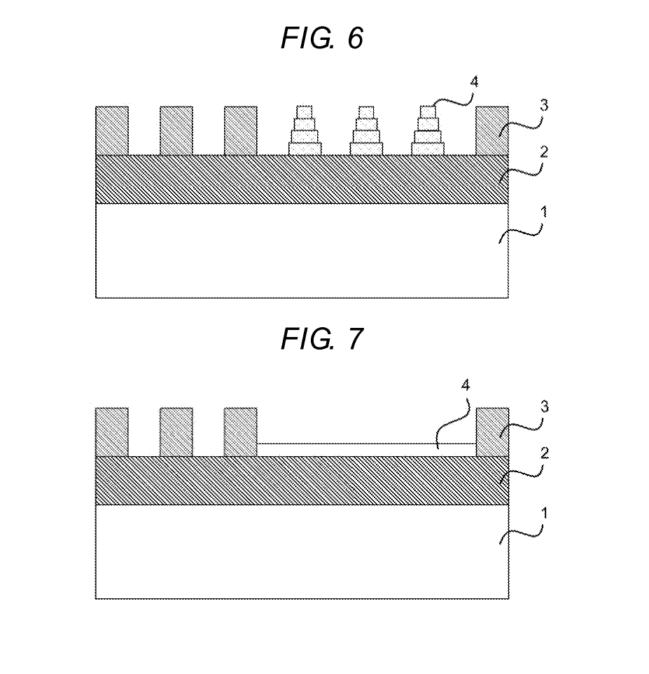

As illustrated in FIG. 5, the dummy pattern 4 is formed by repeating the 3D printing process 8 a plurality of times and so as to print a second layer, and then a third layer, etc., on the first layer to a desired height for the dummy pattern 4. A height of the dummy pattern 4 may be set to a height sufficient to allow etching of the film 2 in a desired manner. Moreover, as illustrated in FIG. 6, by changing a print area of a resin for each height, and laminating the resin, a shape control of the dummy pattern 4 may be performed so that a section of the dummy pattern 4 is in a tapered shape. Since a resin is discharged only to a required region in the inkjet method, there is an advantage of having no waste of 3D printed resin material.

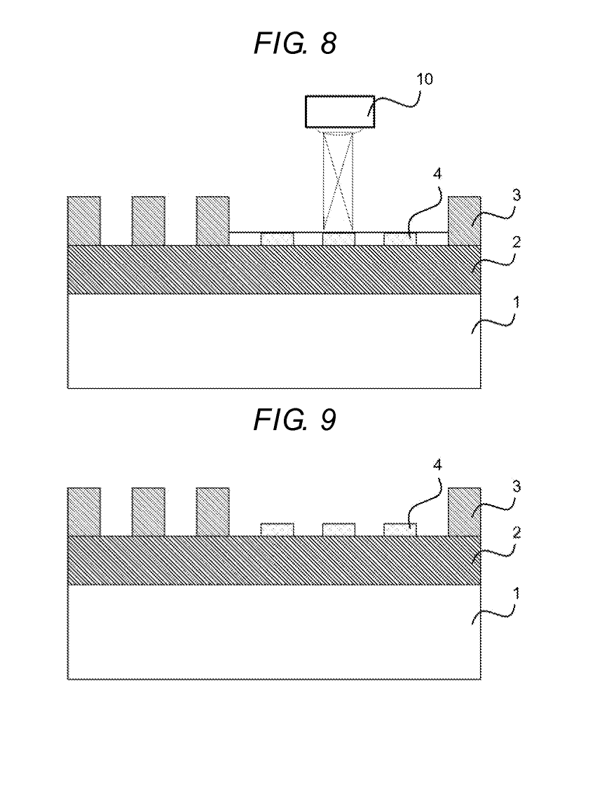

Secondly, a method of using a 3D printer which includes a laser beam mechanism 10 will be described. First, a wafer is set up on a stage of the 3D printer and a liquid resin is applied onto the film 2 as illustrated in FIG. 7. Then, as illustrated in FIG. 8, the resin is cured by irradiating the applied resin with a UV laser beam according to design pattern for the dummy pattern 4. Unnecessary resin which is not cured is subsequently removed by an organic solvent, and thereby a first layer of the dummy pattern 4 is formed as illustrated in FIG. 9. At this time, a height of the dummy pattern 4 is controlled by adjusting a liquid resin application thickness or by repeatedly laminate-printing a second layer, and then a third layer, etc., on the first layer a plurality of times. A printing area of the resin can be changed for each step height of the cured resin, and thereby a vertical shape control such as for producing a tapered shape, such as illustrated in FIG. 6, may be provided.

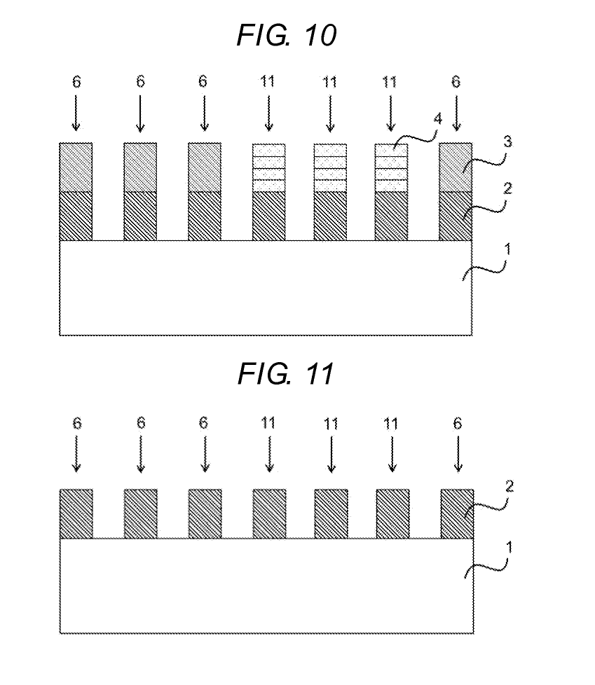

Then, as illustrated in FIG. 10, the film 2 is etched with the resist pattern 3 and the dummy pattern 4 as a mask. As an etching process, dry etching or wet etching can be used.

Then, as illustrated in FIG. 11, the resist pattern 3 and the dummy pattern 4 are removed by asking or wet processing. Accordingly, an underlying pattern 6 is formed by the resist pattern 3, and a dummy underlying pattern 11 is formed by the dummy pattern 4.

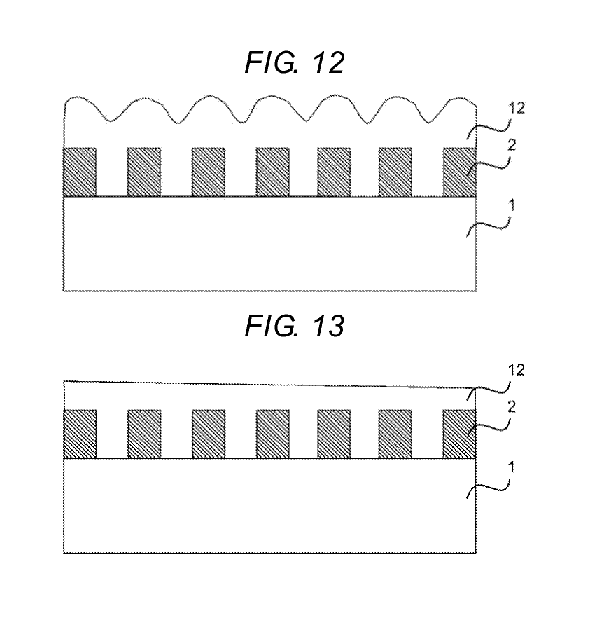

In FIG. 12, the interlayer insulation film 12 is formed on the semiconductor substrate 1 by the CVD method, for example.

In FIG. 13, a surface of the interlayer insulation film 12 is flattened by polishing the interlayer insulation film 12.

As described above, according to the manufacturing method of the semiconductor device according to an exemplary embodiment, the 3D printer is used to form the dummy pattern 4, which is subsequently used in forming a dummy underlying pattern 11 in the chip/die region with a low density underlying pattern 6. Accordingly, it is possible to form the dummy underlying pattern 11 without a need to modify an existing photomask/reticle.

In addition, when forming the dummy pattern 4, decreases in manufacturing time and manufacturing costs are possible by using a 3D printer rather than by using the lithography as in the related art. In addition, the lithography process available for patterning small features (e.g., sub-micron features) is generally limited to exposing a small area at a time and the patterning process must be repeated (stepped) across the wafer to fully pattern the wafer area. However, a 3D printer may be formed to include many columns, such that the dummy pattern 4 may be formed in a large area. It is expected that the 3D printer will form all patterns including a resist pattern 3 and completely replace an exposure device in the future. Moreover, it is possible to form the dummy underlying pattern 11 at an optimum place based on a dispersion of an insulation film thickness on the underlying pattern 6 measured on another wafer (or a statistical average of multiple preceding wafers) in advance or by using data such as the measured color unevenness 7 and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming a resist pattern on a first film using photolithography;
forming a dummy pattern on the first film using a three-dimensional modeling machine, the dummy pattern provided on a region of the first film that is not occupied by the resist pattern;
etching the first film using the resist pattern and the dummy pattern as a mask;
forming a second film on the etched first film; and
planarizing the second film.

2. The method according to claim 1, wherein the three-dimensional modeling machine dispenses a liquid resin by inkjet in forming the dummy pattern.

3. The method according to claim 2, wherein the three-dimensional modeling machine forms the dummy pattern to a desired height on the first film by repeated iterations of laminate-printing.

4. The method according to claim 1, wherein the three-dimensional modeling machine includes a laser.

5. The method according to claim 4, wherein the dummy pattern is formed by selectively irradiating a liquid resin with a laser beam from the laser, the liquid resin being selectively applied to the region of the first film.

6. The method according to claim 1, wherein the region of the first film in which the dummy pattern is formed is determined by:
forming a test resist pattern on a test substrate including a first test film, the test resist pattern substantially matching the resist pattern;
etching the first test film using the test resist pattern as a mask,
forming a second test film on the etched first test film,
planarizing the second test film,
evaluating thickness of the planarized second test film on the test substrate at a plurality of locations so as to locate a sparse region within the test resist pattern, and
locating the region in the resist pattern according to the location of the sparse region in the test resist pattern.

7. The method according to claim 6, wherein evaluating thickness of the second test film at the plurality of locations uses an optical thickness measuring device.

8. The method according to claim 6, wherein a color difference on the test substrate after the second test film is planarized is used to evaluate thickness of the second test film on the test substrate.

9. The method of claim 1, wherein chemical mechanical polishing is used to planarize the second film.

10. The method of claim 1, wherein the first film is a metal film and the second film is an interlayer insulation film.

11. The method of claim 1, wherein an etching rate of the dummy pattern is different from an etching rate of the resist pattern during the etching of the first film.

12. The method of claim 1, wherein the dummy pattern has a feature width which decreases with height from the first film.

13. The method of claim 1, further comprising:
dispensing a liquid resin on the region of the first film that is not occupied by the resist pattern;
using a laser beam from the three-dimensional modeling machine to selectively irradiate the liquid resin and thereby cure a portion of the liquid resin to form a pattern of cured and uncured portions in the liquid resin; and
removing an uncured portion of the liquid resin with a solvent.

14. A method of manufacturing a semiconductor device, comprising:
forming a first pattern on a photomask, the first pattern having regions of high and low pattern density;
using the photomask in a photolithographic process to form a first photo-printed pattern in a photoresist on a first film, the first photo-printed pattern corresponding to the first pattern and having regions of high and low pattern density;
determining a region on the first film in which the first photoresist of the first photo-printed pattern is substantially absent;
using a three-dimensional printer to forma dummy pattern in the region on the first film, the dummy pattern having a pattern density substantially matching a high pattern density region of the first photo-printed pattern;
patterning the first film by simultaneously using the first photo-printed pattern and the dummy pattern as a transfer mask;
forming a second film on the patterned first film; and
planarizing the second film formed on the patterned first film.

15. The method of claim 14, wherein the dummy pattern is formed by depositing a liquid resin on the region of the first film and selectively irradiating portions of the liquid resin thus deposited to form the dummy pattern.

16. The method of claim 14, wherein the three dimensional printer comprises a plurality of inkjet nozzles and the dummy pattern is formed by dispensing a resin through the plurality of inkjet nozzles.

17. The method of claim 14, wherein the determining the region on the first film in which the first photoresist of the first photo-printed pattern is substantially absent includes evaluating film thickness of a test substrate patterned with the photomask and processed without inclusion of the dummy pattern.

18. A method, comprising:
generating a photomask or a reticle corresponding to a first pattern;
using the generated photomask or reticle in a photolithographic process to pattern a first photoresist film on a first wafer according to the first pattern;
transferring the pattern in the first photoresist film to the first wafer;
forming a first film on the first wafer thus patterned;
planarizing the first film on the first wafer;
evaluating film thickness of the planarized first film at a plurality of locations on the first wafer to determine a first region on the first wafer, the first region having a film thickness difference as compared to other regions of the first wafer;
using the generated photomask or reticle in a photolithographic process to pattern a second photoresist film on a second wafer;
using a three dimensional modeling machine to form a dummy resist pattern in a second region of the second wafer, the second region substantially corresponding in position to the first region of the first wafer; and
transferring the pattern in the second photoresist film and the dummy resist pattern to the second wafer.

19. The method of claim 18, wherein the three dimensional modeling machine comprises a plurality of inkjet nozzles.

20. The method of claim 18, wherein the three dimensional modeling machine comprises a laser, and the dummy resist pattern is formed by using the laser to selectively irradiate portions of a liquid resin deposited on the second region.
